(19) United States
(12) Patent Application Publication
(10) Pub. No.: US 2023/0213866 A1
(43) Pub. Date: Jul. 6, 2023

(54) SUBSTRATE TREATMENT APPARATUS AND SUBSTRATE TREATMENT METHOD

(71) Applicant: SEMES CO., LTD., Cheonan-si (KR)

(72) Inventors: Hyun YOON, Seoul (KR); Ji Hoon Jeong, Hwaseong-si (KR); Young Dae Chung, Incheon (KR); Ki Hoon Choi, Cheonan-si (KR)

(73) Assignee: SEMES CO.,LTD., Cheonan-si (KR)

(21) Appl. No.: 18/147,473

(22) Filed: Dec. 28, 2022

(30) Foreign Application Priority Data
Dec. 30, 2021 (KR) 10-2021-0192289
Apr. 28, 2022 (KR) 10-2022-0052509

(51) Int. Cl. G03F 7/20; G03F 1/60

(52) U.S. Cl. CPC G03F 7/70158; G03F 1/60; G03F 7/70025

(57) ABSTRACT

The present disclosure relates to an apparatus for treating a substrate. The substrate treatment apparatus includes a support unit that supports a substrate, a liquid supply unit that supplies a liquid to the substrate supported by the support unit, and a laser unit that heats the substrate supported by the support unit, wherein the laser unit includes an oscillation unit that emits a light, and a diffraction unit that separates the light into a plurality of light bundles and irradiates the substrate supported by the support unit with an adjustment light having a profile changed from a profile of the light.

### CROSS-REFERENCE TO RELATED APPLICATIONS

This application claims priority under 35 U.S.C. § 119 to Korean Patent Application No. 10-2021-0192289 filed on Dec. 30, 2021 and Korean Patent Application No. 10-2022-0052509 filed on Apr. 28, 2022, in the Korean Intellectual Property Office, the disclosures of which are incorporated by reference herein in their entireties.

### BACKGROUND

Embodiments of the present disclosure relates to a substrate treatment apparatus and a substrate treatment method, and more particularly, to an apparatus for treating a substrate by heating the substrate and a method of treating a substrate.

A photographic process for forming a pattern on a wafer includes an exposure process. The exposure process is a preliminary process for cutting a semiconductor-integrated material attached to the wafer into a desired pattern. The exposure process may have various purposes such as forming a pattern for etching and forming a pattern for ion implantation. In the exposure process, a pattern is drawn with light on the wafer using a mask that is a kind of “frame.” When a semiconductor-integrated material on the wafer, for example, a resist on the wafer, is exposed to light, chemical properties of the resist are changed according to the pattern drawn by the light and the mask. When a developing solution is supplied to the resist of which the chemical properties are changed according to the pattern, a pattern is formed on the wafer.

To precisely perform the exposure process, the pattern formed on the mask should be precisely manufactured. Whether the pattern is formed under the required process condition should be identified. A large number of patterns may be formed in the one mask. Accordingly, a long time is consumed to inspect all the large number of patterns for an operator to inspect the one mask. Accordingly, a monitoring pattern capable of representing one pattern group including the plurality of patterns is formed on the mask. Further, an anchor pattern capable of representing the plurality of pattern groups is formed on the mask. The operator may estimate whether the patterns included in the one pattern group are good or bad through inspecting the monitoring pattern. Further, the operator may estimate whether the patterns formed on the mask are good or bad through inspecting the anchor pattern.

Further, it is preferable that the monitoring pattern and the anchor pattern have the same critical dimension to increase inspection accuracy of the mask. A critical dimension correction process for correcting the critical dimensions of the patterns formed on the mask is additionally performed.

FIG. 1 illustrates a normal distribution of a first critical dimension CDP 1 of the monitoring pattern and a second critical dimension CDP2 of the anchor pattern of the mask before the critical dimension correction process is performed during a mask manufacturing process. Further, the line width CDP1 and the second line width CDP2 have a small size than a desired line width. The critical dimensions CD of the monitoring pattern and the anchor pattern are intentionally deviated before the critical dimension correction process is performed. Further, in the critical dimension correction process, the anchor pattern is additionally etched, and thus the critical dimensions of these two patterns are the same. In the process of additionally etching the anchor pattern, when the anchor pattern is more etched than the monitoring pattern, a difference between the critical dimensions of the monitoring pattern and the anchor pattern occurs, and thus the critical dimensions of the patterns formed on the mask cannot be precisely corrected. When the anchor pattern is additionally etched, precise etching of the anchor pattern should be accompanied.

In the process of etching the anchor pattern, a treatment liquid is supplied to the mask, the anchor pattern formed on the mask to which the treatment liquid is suppled is heated using a laser beam. To perform precise etching on the anchor pattern, a specific region in which the anchor pattern is formed should be precisely irradiated with the laser beam. To this end, a profile of the laser beam with which the anchor pattern is irradiated should be accurately set according to a process requirement condition. The profile is a concept including the intensity of the laser beam with which the anchor pattern is irradiated, the diameter of the light, a distribution (focus dispersion) of the laser beam, or the like.

A working distance between the heat-treated mask and a head irradiated with the laser beam may be changed according to various reasons. When the working distance is changed, the profile of the laser beam with which the mask is irradiated is changed. Accordingly, it is difficult to accurate irradiate the anchor pattern with the laser beam, and the critical dimension correction process cannot be precisely performed. Thus, process defects are caused, and process uniformity is degraded.

### SUMMARY

Embodiments of the present disclosure provide a substrate treatment apparatus and method capable of performing precise etching on a substrate.

Further, embodiments of the present disclosure also provide a substrate treatment apparatus and method capable of performing selective etching on a specific region of the substrate.

Further, embodiments of the present disclosure also provide a substrate treatment apparatus and method capable of performing uniform etching on a specific region of the substrate.

Further, embodiments of the present disclosure also provide a substrate treatment apparatus and method capable of flexibly changing a profile of a laser beam with which the substrate is irradiated.

The problem to be solved by the present disclosure is not limited to the above-described problems, and not-mentioned problems will be clearly understood by those skilled in the art to which the present disclosure pertains from the present specification and the accompanying drawings.

The present disclosure provides a substrate treatment apparatus. The substrate treatment apparatus includes a support unit that supports a substrate, a liquid supply unit that supplies a liquid to the substrate supported by the support unit, and a laser unit that heats the substrate supported by the support unit, wherein the laser unit includes an oscillation unit that emits a light, and a diffraction unit that separates the light into a plurality of light bundles and irradiates the substrate supported by the support unit with an adjustment light having a profile changed from a profile of the light.

According to an embodiment, the profile may include an intensity of light per unit area.

According to an embodiment, the diffraction unit may be provided to movable on a path of the light emitted from the oscillation unit.

According to an embodiment, the light path may include a first region and a second region different from the first region, the substrate treatment apparatus may further include a controller, and the controller may move the diffraction unit in a direction toward the first region, separate the light input to the first region among the light emitted from the oscillation unit into a plurality of light bundles, and change the profile of the light so that an intensity per unit area of the light in the first region is greater than an intensity per unit area of the light in the second region, the light passing through the diffraction unit.

According to an embodiment, the laser unit may further include an expander that changes a diameter of the light, and the expander is provided between the oscillation unit and the diffraction unit.

According to an embodiment, the profile may further include the diameter of the light or a distribution of the light, the expander may include a plurality of lenses, and the controller changes the profile of the light by changing a distance between the plurality of lenses on the light path.

According to an embodiment, the laser unit may further include a capturing member that captures the adjustment light on the support unit, and an irradiation direction of the adjustment light with which the substrate supported by the support unit is irradiated and a capturing direction of the capturing member may have the same axis when viewed from the top.

Further, the present disclosure provides a substrate treatment apparatus for treating a mask having a plurality of cells. The substrate treatment apparatus includes a support unit that supports the mask in which a first pattern is formed inside the plurality of cells and a second pattern different from the first pattern is formed outside regions in which the cells are formed, a liquid supply unit that supplies a liquid to the mask supported by the support unit, and a laser unit that heats the mask supported by the support unit, wherein the laser unit includes an oscillation unit that emits light, an expander that changes a diameter of the light, and a diffraction unit that separates the light into a plurality of light bundles and irradiates a substrate supported by the support unit with an adjustment light having a profile changed from a profile of the light.

According to an embodiment, the profile may include an intensity of the light per unit area, a diameter of the light, or a distribution of the light.

According to an embodiment, the diffraction unit may be provided to movable on a path of the light emitted from the oscillation unit.

According to an embodiment, the expander may be provided between the oscillation unit and the diffraction unit.

According to an embodiment, the light path may include a first region and a second region different from the first region, the substrate treatment apparatus may further include a controller, and the controller may move the diffraction unit in a direction toward the first region, separate the light input to the first region among the light emitted from the oscillation unit into a plurality of light bundles, and change the profile of the light so that an intensity per unit area of the light in the first region is greater than an intensity per unit area of the light in the second region, the light passing through the diffraction unit.

According to an embodiment, the expander may include a plurality of lenses, and the controller changes the profile of the light by changing a distance between the plurality of lenses on the light path.

According to an embodiment, the laser unit may further include a capturing member that captures the adjustment light with which the substrate supported by the support unit is irradiated, and an irradiation direction of the adjustment light with which the substrate supported by the support unit is irradiated and a capturing direction of the capturing member may have the same axis when viewed from the top.

According to an embodiment, the laser unit may irradiate the second pattern among the first pattern and the second pattern with the adjustment light.

Further, the present disclosure provides a substrate treatment method. The substrate treatment method is provided such that a substrate is treated by supplying a liquid to a substrate supported by a support unit and irradiating the substrate to which the liquid is supplied with an adjustment light having a adjusted profile, the adjustment light with which the substrate is irradiated is provided by separating a light emitted from an oscillation unit into a plurality of light bundles, and the profile includes an intensity of light per unit area, a diameter of the light, and a distribution of the light.

According to an embodiment, the diffraction unit that separates the light into the light bundles may move on a path of the light emitted from the oscillation unit.

According to an embodiment, the light path may include a first region and a second region different from the first region, and the diffraction unit may move in a direction toward the first region, the light input into the first region among the light emitted from the oscillation unit may be separated into the plurality of light bundles, and the profile of the light may be changed so that an intensity per unit area of the light in the first region is greater than an intensity per unit area of the light in the second region, the light passing through the diffraction unit.

According to an embodiment, the profile of the light may be changed by changing the diameter of the light between the oscillation unit and the diffraction unit.

According to an embodiment, the substrate may be provided as a mask having a plurality of cells, a first pattern may be formed inside the plurality of cells in the mask, a second pattern different from the first pattern may be formed outside a region in which the cells are formed, and the second pattern may be irradiated with the adjustment light.

### BRIEF DESCRIPTION OF THE FIGURES

The above and other objects and features of the present disclosure will become apparent by describing in detail embodiments thereof with reference to the accompanying drawings.

FIG. 1 is a view illustrating a normal distribution related to a critical dimension of a monitoring pattern and a critical dimension of an anchor pattern;

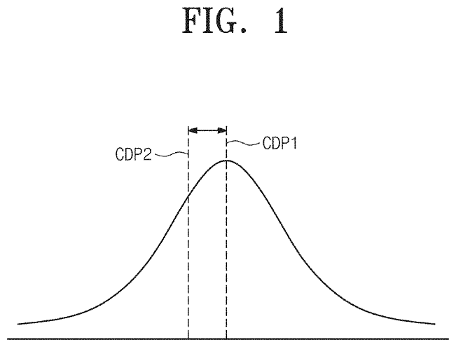

FIG. 2 is a schematic plan view illustrating a substrate treatment apparatus according to an embodiment of the present disclosure;

FIG. 3 is a schematic view illustrating a state when a substrate treated in a liquid treatment chamber of FIG. 2 is viewed from the top;

FIG. 4 is a schematic view illustrating the liquid treatment chamber of FIG. 2 according to the embodiment;

FIG. 5 is a view when the liquid treatment chamber of FIG. 4 according to the embodiment is viewed from the top;

FIG. 6 is a schematic view illustrating a state in which a laser unit of FIG. 4 according to the embodiment is viewed from the lateral side;

FIG. 7 is a schematic view illustrating a state when the laser unit of FIG. 6 according to the embodiment is viewed from the top;

FIG. 8 is a schematic view illustrating a state in which an expander and a diffraction unit of FIG. 6 according to the embodiment are viewed from the lateral side;

FIG. 9 is a schematic view illustrating a state in which the diffraction unit of FIG. 8 according to the embodiment is viewed from the front side;

FIG. 10 is a schematic view illustrating a state of light moving along a light path and having a reference profile in the laser unit of FIG. 6 according to the embodiment;

FIG. 11 is a schematic view illustrating a state in which the expander of FIG. 6 according to the embodiment changes a profile of light having the reference profile;

FIGS. 12 and 13 are schematic views illustrating a state in which the diffraction unit of FIG. 6 according to the embodiment changes the profile of light having the reference profile;

FIG. 14 is a schematic view illustrating a state in which a light having a changed profile of FIG. 12 and a light having a changed profile of FIG. 13 are viewed from the front side; and

FIG. 15 is a view illustrating comparison in the embodiment in which the profile of the light is changed in the laser unit of FIG. 6 according to the embodiment.

### DETAILED DESCRIPTION

Hereinafter, embodiments of the present disclosure will be described in more detail with reference to the accompanying drawings. Embodiments of the present disclosure may be modified in various forms, and the scope of the present disclosure should not be construed as being limited by the embodiments described below. The present embodiments are provided to more completely describe the present disclosure to those skilled in the art. Thus, the shapes and the like of components in the drawings are exaggerated in order to emphasize a clearer description.

The terms such as first and second may be used to describe various elements, but the elements are not limited to the terms. The terms may be used only for the purpose of distinguishing one element from another element. For example, while not deviating from the scope of the present disclosure, a first element may be named a second element, and similarly, the second element may be named the first element.

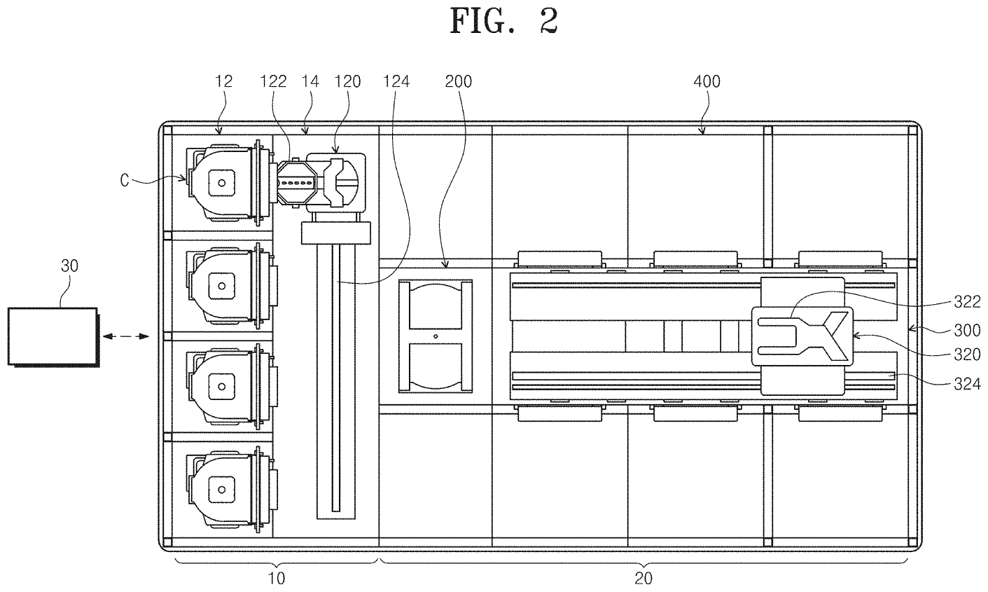

Hereinafter, embodiments of the present disclosure will be described in detail with reference to FIGS. 2 to 15. FIG. 2 is a schematic plan view illustrating a substrate treatment apparatus according to an embodiment of the present disclosure.

Referring to FIG. 2, the substrate treatment apparatus includes an index module 10, a treating module 20, and a controller 30. According to the embodiment, when viewed from the top, the index module 10 and the treating module 20 may be arranged in one direction.

The index module 10 transports a substrate “M”. The index module 10 transports the substrate “M” between a container “C” in which the substrate “M” is accommodated and the treating module 20. For example, the index module 10 transports, to the container “C”, the substrate “M” on which predetermined treatment is completed in the treating module 20. For example, the index module 10 transports, from the container “C” to the treating module 20, the substrate “M” on which the predetermined treatment is scheduled in the treating module 20. When viewed from the top, a lengthwise direction of the index module 10 may be a direction perpendicular to a direction in which the index module 10 and the treating module 20 are arranged. The index module 10 may have a load port 12 and an index frame 14.

The container “C” in which the substrate “M” is accommodated is seated in the load port 12. The load port 12 may be positioned on an opposite side of the treating module 20 with respect to the index frame 14. A plurality of load ports 12 may be provided. The plurality of load ports 12 maybe arranged in a line in the lengthwise direction of the index module 10. The number of load ports 12 may be increased or decreased according to process efficiency and a footprint condition of the treating module 20.

An airtight container such as a front opening unified pod (FOUP) may be used as the container “C”. The container “C” may be placed on the load port 12 by an operator or a transfer unit (not illustrated) such as an overhead transfer, an overhead conveyor, or an automatic guided vehicle.

The index frame 14 provides a transport space through which the substrate “M” is transported. An index robot 120 and an index rail 124 are provided in the transport space of the index frame 14. The index robot 120 transports the substrate “M”. The index robot 120 may transport the substrate “M” between the index module 10 and a buffer unit 200, which will be described below. The index robot 120 has an index hand 122.

The substrate “M” is placed on the index hand 122. The index hand 122 may be provided to be capable of forward and rearward movement, rotation using a vertical direction as an axis, and movement along an axial direction. A plurality of index hands 122 may be provided. The plurality of index hands 122 may be spaced apart from each other in the vertical direction. The plurality of index hands 122 may be provided to move forward and rearward independently of each other.

The index rail 124 is provided in the transport space of the index frame 14. The index rail 124 is provided such that a lengthwise direction thereof is parallel to a lengthwise direction of the index frame 14. The index robot 120 is placed on the index rail 124, and the index robot 120 is provided to be a linearly movable on the index rail 124. That is, the index robot 120 may move forward or rearward on the index rail 124.

The controller 30 may control the substrate treatment apparatus 1. Further, the controller 30 may include a process controller including a microprocessor (computer) that executes control of the substrate treatment apparatus 1, a user interface including a keyboard for inputting commands to allow an operator to manage the substrate treatment apparatus 1 and a display that visualizes and displays an operation situation of the substrate treatment apparatus 1, and a memory unit for storing a control program for executing processing executed by the substrate treatment apparatus 1 under a control of the process controller or a program for executing processing in components according to various data and processing conditions, that is, a processing recipe. Further, the user interface and the memory unit may be connected to the process controller. The processing recipe may be stored in a memory medium of the memory unit, and the memory medium may be a hard disk, and may be a transportable disk such as a CD-ROM and a DVD and a semiconductor memory such as a flash memory.

The controller 30 may control components of the substrate treatment apparatus 1 to perform the following substrate treatment method. For example, the controller 30 may control components in provided in a liquid treatment chamber 400 to perform the following substrate treatment method.

The treating module 20 may include the buffer unit 200, a transport frame 300, and the liquid treatment chamber 400.

The buffer unit 200 provides a buffer space in which the substrate “M” carried in the treating module 20 and the substrate “M” carried out of the treating module 20 stay temporarily. The buffer unit 200 may be disposed between the index frame 14 and the transport frame 300. The buffer unit 200 may be positioned at one end of the transport frame 300. The buffer unit 200 is provided with a slot therein (not illustrated) on which the substrate “M” is placed. A plurality of slots (not illustrated) may be provided. The plurality of slots (not illustrated) may be spaced apart from each other in the vertical direction.

A front face and a rear face of the buffer unit 200 are open. The front face is a surface facing the index frame 14, and the rear face is a surface facing the transport frame 300. The index robot 120 may approach the buffer unit 200 through the front face, and a transport robot 320, which will be described below, may approach the buffer unit 200 through the rear face.

The transport frame 300 provides a space through which the substrate “M” is transported between the buffer unit 200 and the liquid treatment chamber 400. A lengthwise direction of the transport frame 300 may be a direction parallel to a direction in which the index module 10 and the treating module 20 are arranged. The liquid treatment chambers 400 may be arranged on both sides of the transport frame 300. According to the embodiment, the liquid treatment chambers 400 may be arranged on both sides of the transport frame 300. The liquid treatment chambers 400 provided on one side of the transport frame 300 may be provided in an array of A×B (wherein, A and B are 1 or a natural number greater than 1) in the lengthwise direction and the vertical direction of the transport frame 300.

The transport frame 300 has the transport robot 320 and a transport rail 324. The transport robot 320 transports the substrate “M”. The transport robot 320 transports the substrate “M” between the buffer unit 200 and the liquid treatment chamber 400. The transport robot 320 includes a transport hand 322 on which the substrate “M” is placed. The substrate “M” may be placed on the transport hand 322. The transport hand 322 may be provided to be capable of forward and rearward movement, rotation about a vertical direction, and movement along an axial direction. A plurality of transport hands 322 may be spaced apart from each other in the vertical direction, and the plurality of transport hands 322 may move forward or rearward independently of each other.

The transport rail 324 may be provided inside the transport frame 300 in a lengthwise direction of the transport frame 300. The transport robot 320 is placed on the transport rail 324, and the transport robot 320 is provided to be a movable on the transport rail 324.

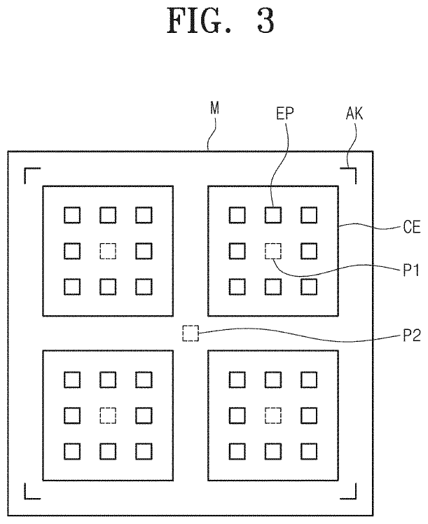

FIG. 3 is a schematic view illustrating a state when a substrate treated in a liquid treatment chamber of FIG. 2 is viewed from the top. Hereinafter, the substrate “M” treated in the liquid treatment chamber 400 according to the embodiment of the present disclosure will be described in detail with reference to FIG. 3.

Referring to FIG. 3, a to-be-treated object treated in the liquid treatment chamber 400 may be one substrate among a wafer, a glass, and a photo mask. The substrate “M” treated in the liquid treatment chamber 400 according to the embodiment of the present disclosure may be a photo mask that is a kind of “frame” used during the exposure process. For example, the substrate “M” may have a quadrangular shape. A reference mark AK, a first pattern P1, and a second pattern P2 may be formed on the substrate “M”.

At least one reference mark AK may be formed on the substrate “M”. For example, the plurality of reference marks AK may be formed at corner regions of the substrate “M”. The reference mark AK may be a mark called an align key and used when the substrate “M” is aligned. Further, the reference mark AK may be a mark used to derive positional information on the substrate “M”. For example, a capturing member 700, which will be described below, may photograph the reference mark AK, acquire an image thereof, and transmit the acquired image to the controller 30. The controller 30 may analyze the image including the reference mark AK to detect an exact position of the substrate “M”. Further, the reference mark AK may be used to identify the position of the substrate “M” when the substrate “M” is transported.

A cell CE may be formed on the substrate “M”. At least one cell CE may be formed. For example, a plurality of cells CE may be formed. A plurality of patterns may be formed in the plurality of cells CE, respectively. The patterns formed in the cells CE may be defined as one pattern group. The patterns formed in the cells CE may include an exposure pattern EP and the first pattern P1.

The exposure pattern EP may be used to form an actual pattern on the substrate “M”. The first pattern P1 may be a pattern representing the exposure patterns EP formed in one cell CE. When the plurality of cells CE are provided, the plurality of first patterns P1 may be provided.

For example, the first pattern P1 may be provided in the plurality of cells CE, respectively. However, the present disclosure is not limited thereto, and the plurality of first patterns P1 may be formed in the one cell CE.

The first pattern P1 may have a shape in which portions of the exposure patterns EP are combined. The first pattern P1 may be called a monitoring pattern. An average value of the critical dimensions of the plurality of first patterns P1 may be called a critical dimension monitoring macro (CDMM).

When the operator inspects the first pattern P1 formed in any one cell CE through a scanning electron microscope (SEM), whether the shapes of the exposure patterns EP formed in any one cell CE are good or bad may be estimated. Accordingly, the first pattern P1 may function as an inspection pattern. Unlike the above description, the first pattern P1 may be any one pattern among the exposure patterns EP actually participating in the exposure process. Selectively, the first pattern P1 may be an inspection pattern, and at the same time, a pattern actually participating in the exposure process.

The second pattern P2 may be formed outside the cells CE formed on the substrate “M”. For example, the second pattern P2 may be positioned outside a region in which the plurality of cells CE are provided. The second pattern P2 may be a pattern representing the exposure patterns EP formed in the substrate “M”. At least one second pattern P2 may be provided. For example, a plurality of second patterns P2 may be provided. The plurality of second patterns P2 may be arranged in series and/or parallel combinations. Selectively, the plurality of second patterns P2 may have a shape in which some of the first patterns P1 are combined.

When the operator inspects the second pattern P2 through the SEM, whether the shapes of the exposure patterns EP formed the one substrate “M” are good or bad may be estimated. Accordingly, the second pattern P2 may function as an inspection pattern. The second pattern P2 may be an inspection pattern that does not actually participate in the exposure process. The second pattern P2 may be a pattern for setting a processing condition of an exposure device. The second pattern P2 may be called an anchor pattern.

Hereinafter, the liquid treatment chamber 400 according to the embodiment of the present disclosure will be described in detail. Further, hereinafter, a treatment process performed by the liquid treatment chamber 400 will be described as an example in which fine critical dimension correction (FCC) is performed during a process of manufacturing a mask for the exposure process.

The substrate “M” treated by the liquid treatment chamber 400 may be the substrate “M” on which pre-treatment is performed. The critical dimensions of the first pattern P1 and the second pattern P2 formed on the substrate “M” carried in the liquid treatment chamber 400 may be different from each other. According to the embodiment, the critical dimension of the first pattern P1 may be greater than the critical dimension of the second pattern P2. For example, the critical dimension of the first pattern P1 may have a first width (for example, 69 nm), and the critical dimension of the second pattern P2 may be a second width (for example, 68.5 nm).

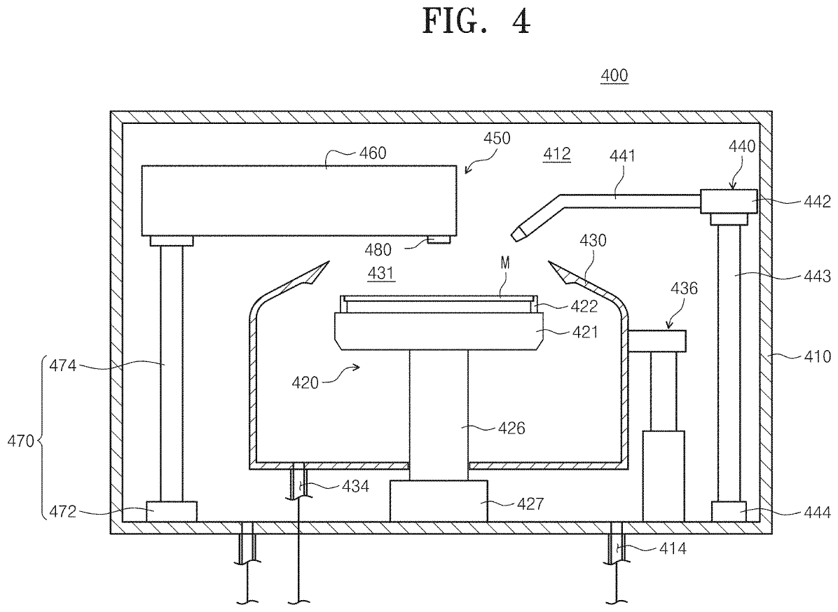

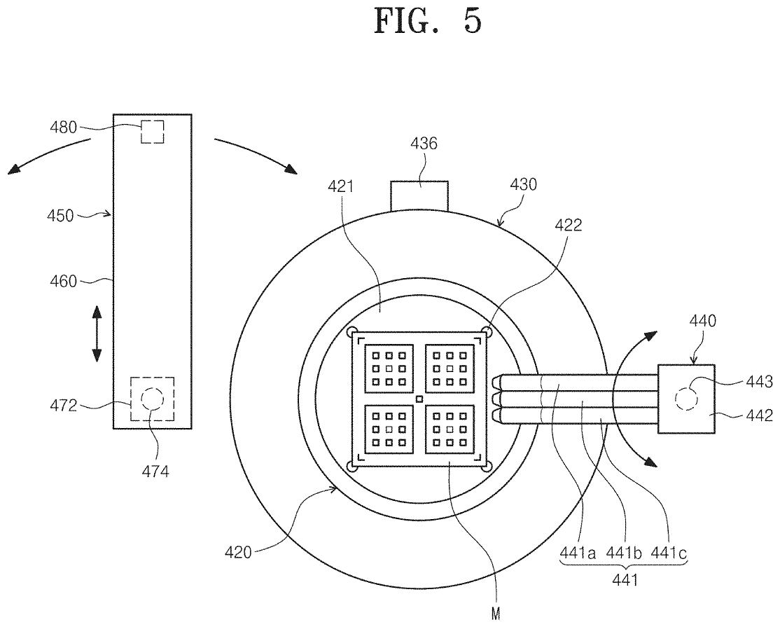

FIG. 4 is a schematic view illustrating the liquid treatment chamber of FIG. 2 according to the embodiment. FIG. 5 is a view when the liquid treatment chamber of FIG. 4 according to the embodiment is viewed from the top. Referring to FIGS. 4 and 5, the liquid treatment chamber 400 may include a housing 410, a support unit 420, a treatment container 430, a liquid supply unit 440, and a laser unit 450.

The housing 410 has an internal space 412. The internal space 412 is provided with the support unit 420, the treatment container 430, the liquid supply unit 440, and the laser unit 450. An opening (not illustrated) through which the substrate “M” is carried in or out may be formed in the housing 410. An inner wall of the housing 410 may be coated with a material having high corrosion resistance to a liquid supplied by the liquid supply unit 440.

An exhaust hole 414 is formed in a bottom surface of the housing 410. The exhaust hole 414 may be connected to a pressure reduction member (not illustrated). For example, the pressure reduction member (not illustrated) may be provided as a pump. The exhaust hole 414 exhausts an atmosphere of the internal space 412. Further, the exhaust hole 414 discharges by-products generated in the internal space 412 to the outside of the internal space 412.

The support unit 420 supports the substrate “M” in the internal space 412. Further, the support unit 420 rotates the substrate “M”. The support unit 420 supports and rotates the substrate “M” in a treatment space 431, which will be described below. The support unit 420 may include a body 421, a support pin 422, a support shaft 426, and a driving machine 427.

The body 421 may be provided substantially in a plate shape. The body 421 may have a plate shape having a certain thickness. When viewed from the top, the body 421 may have an upper surface provided in a substantially circular shape. The upper surface of the body 421 may have a greater area than the substrate “M”.

The support pin 422 supports the substrate “M”. The support pin 422 supports the substrate “M” so that a bottom surface of the substrate “M” and the upper surface of the body 421 are spaced apart from each other. When viewed from the top, the support pin 422 may have a substantially circular shape. When viewed from the top, the support pin 422 may have a shape in which a portion corresponding to an edge region of the substrate “M” is recessed downward.

The support pin 422 may have a first surface and a second surface. For example, the first surface may support a lower portion of the edge region of the substrate “M”. The second surface may face a side portion of the edge region of the substrate “M”. Accordingly, when the substrate “M” is rotated, movement of the substrate “M” in the lateral direction may be restricted by the second surface.

A plurality of support fins 422 are provided. The number of support pins 422 may correspond to the number of edge regions of the substrate “M” having a quadrangular shape. For example, four support pins 422 may be provided.

The support shaft 426 is coupled to the body 421. The support shaft 426 is positioned below the body 421. The support shaft 426 may move in a vertical direction by the driving machine 427. The support shaft 426 may rotate by the driving machine 427. The driving machine 427 may be a motor. When the driving machine 427 rotates the support shaft 426, the body 421 coupled to the support shaft 426 may rotate. The substrate “M” may rotate with rotation of the body 421 by means of the support pin 422.

The support shaft 426 may be a hollow shaft. Further, the driving machine 427 may be a hollow motor. A fluid supply line not illustrated may be formed inside the hollow shaft to supply a fluid to a lower portion of the substrate “M”. The fluid supplied to the lower portion of the substrate “M” may be a chemical, a rinsing liquid, or an inert gas. However, unlike the above description, the fluid supply line (not illustrated) may not be provided inside the support shaft 426.

The treatment container 430 has the treatment space 431. The treatment container 430 has the treatment space 431 in which the substrate “M” is treated. The treatment container 430 may have a top-opened cylindrical shape. The substrate “M” may be subjected to liquid treatment and heat treatment inside the treatment space. The treatment container 430 may prevent the liquid supplied to the substrate “M” from being scattered to the housing 410, the liquid supply unit 440, and the laser unit 450.

When viewed from the top, an opening into which the support shaft 426 is inserted may be formed in a bottom surface of the treatment container 430. A discharge hole 434 through which the liquid supplied by the liquid supply unit 440 may be discharged to the outside may be formed in the bottom surface of the treatment container 430. A side surface of the treatment container 430 may extend upward from the bottom surface. An upper end of the treatment container 430 may be inclined. For example, the upper end of the treatment container 430 may extend upward from the ground toward the substrate “M” supported by the support unit 420.

The treatment container 430 is coupled to an elevation member 436. The elevation member 436 may vertically move the treatment container 430. The elevation member 436 may be a driving device capable of vertically moving the treatment container 430. The elevation member 436 may move the treatment container 430 in an upward direction while the substrate “M” is subjected to the liquid treatment or the heat treatment. In this case, the upper end of the treatment container 430 may be positioned higher than an upper end of the substrate “M” supported by the support unit 420. When the substrate “M” is carried in the internal space 412 or when the substrate “M” is carried out from the internal space 412, the elevation member 436 may move the treatment container 430 in a downward direction.

The liquid supply unit 440 supplies the liquid onto the substrate “M”. The liquid supported by the liquid supply unit 440 to the substrate “M” may be provided as a treatment liquid. For example, the treatment liquid may be provided as an etching liquid or a rinsing liquid. The etching liquid may be a chemical. The etching liquid may etch the pattern formed on the substrate “M”. The etching liquid may be called an etchant. The etchant may be a liquid containing a mixture of ammonia, water, and additives and hydrogen peroxide. The rinsing liquid may clean the substrate “M”. The rinsing liquid may be provided as a known medicinal liquid.

The liquid supply unit 440 may include a nozzle 441, a fixed body 442, a rotary shaft 443, and a rotation driving machine 444.

The nozzle 441 may supply the liquid to the substrate “M” supported by the support unit 420. One end of the nozzle 441 may be coupled to the fixed body 442, and the other end of the nozzle 441 may extend from the fixed body in a direction toward the substrate “M”. The other end of the nozzle 441 may extend to be bent by a certain angle in a direction toward the substrate “M” supported by the support unit 420.

As illustrated in FIG. 5, the nozzle 441 may include a first nozzle 441a, a second nozzle 441b, and a third nozzle 441c. The first nozzle 441a, the second nozzle 441b, and the third nozzle 441c may supply different liquids to the substrate “M”. For example, any one among the first nozzle 441a, the second nozzle 441b, and the third nozzle 441c may supply the chemical among the above-described treatment liquid. Further, another one among the first nozzle 441a, the second nozzle 441b, and the third nozzle 441c may supply the rinsing liquid among the above-described treatment liquid. The other one among the first nozzle 441a, the second nozzle 441b, and the third nozzle 441c may supply a chemical that is different from the chemical supplied by any one among the first nozzle 441a, the second nozzle 441b, and the third nozzle 441c.

The fixed body 442 may fixedly support the nozzle 441. The fixed body 442 may be coupled to the rotary shaft 443. One end of the rotary shaft 443 is coupled to the fixed body 442, and the other end of the rotary shaft 443 may be coupled to the rotation driving machine 444. The rotation driving machine 444 rotates the rotary shaft 443. The rotary shaft 443 may have a vertically lengthwise direction. The rotary shaft 443 may rotate about a vertical axis. When the rotation driving machine 444 rotates the rotary shaft 443, the fixed body 442 may rotate about the vertical axis. Accordingly, discharge ports of the nozzles 441a, 441b, and 441c may move between a liquid supply position in which the liquid is supplied to the substrate “M” and a standby position in which the liquid is not supplied to the substrate “M”.

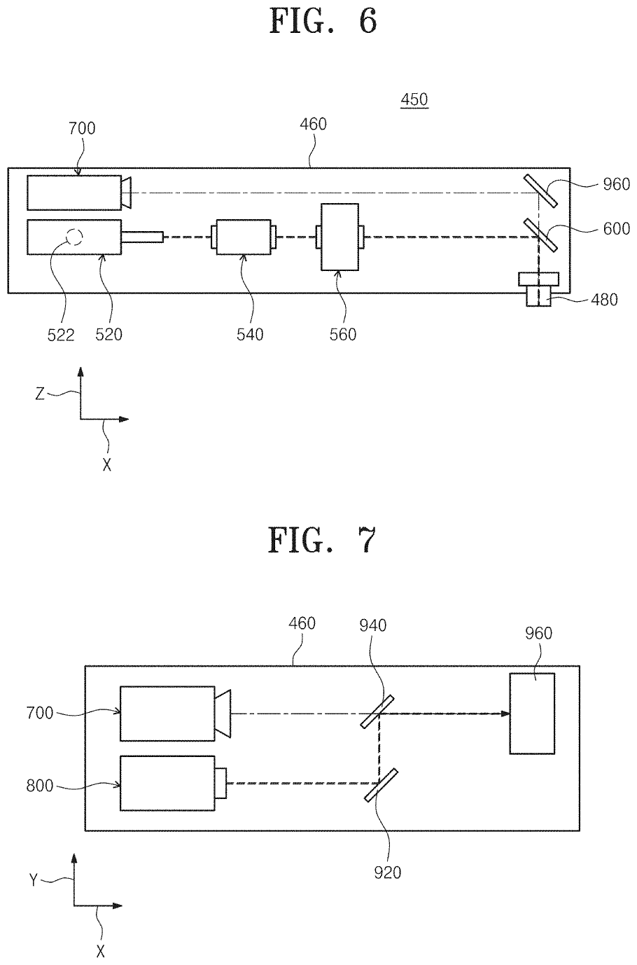

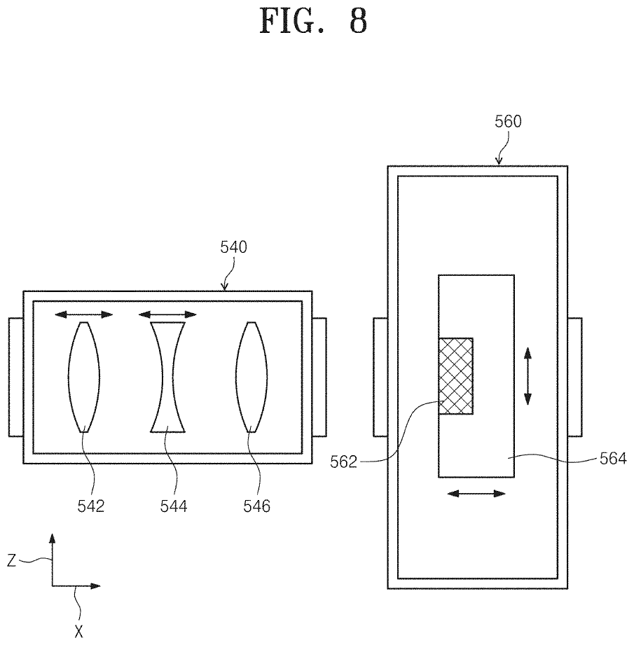

FIG. 6 is a schematic view illustrating a state in which a laser unit of FIG. 4 according to the embodiment is viewed from the lateral side. FIG. 7 is a schematic view illustrating a state when the laser unit of FIG. 6 according to the embodiment is viewed from the top.

Hereinafter, the laser unit according to the embodiment of the present disclosure will be described in detail with reference to FIGS. 4 to 7. As illustrated in FIGS. 6 and 7, hereinafter, for convenience of understanding, a direction in which components 520, 540, and 560 included in an irradiation member 500 are arranged is defined as a first direction X. Further, a direction perpendicular to the first direction X when viewed from the top is defined as a second direction Y, and a direction perpendicular to a plane including both the first direction X and the second direction Y is defined as a third direction Z.

As illustrated in FIG. 4, the laser unit 450 is positioned in the internal space 412. The laser unit 450 heats the substrate “M”. The laser unit 450 may heat the substrate “M” to which the liquid is supplied. For example, after the liquid is supplied onto the substrate “M” by the liquid supply unit 440, the laser unit 450 may heat a specific region of the substrate “M” by irradiating, with light, the substrate “M” on which a liquid film is formed. For example, the laser unit 450 may irradiate the second pattern P2 formed in the specific region of the substrate “M” with light. For example, the light with which the laser unit 450 irradiates the substrate “M” may be a laser beam. The temperature of the specific region of the substrate “M” irradiated with the light may increase. Accordingly, the etching degree of the second pattern P2 of the region irradiated with light by the liquid may increase. Further, the laser unit 450 may acquire an image of light with which the substrate “M” is irradiated.

The laser unit 450 may include a housing 460, a movement member 470, a head member 480, the irradiation member 500, a lower reflective plate 600, the capturing member 700, a lighting member 800, and an upper reflective member 900.

As illustrated in FIGS. 6 and 7, an installation space is provided inside the housing 460. The installation space of the housing 460 may provide an environment sealed from the outside. A portion of the head member 480, the irradiation member 500, the capturing member 700, and the lighting member 800 may be positioned in the installation space of the housing 460. The irradiation member 500, the capturing member 700, and the lighting member 800, which are positioned in the installation space of the housing 460, are protected from byproducts or scattered liquid generated during the treatment process. The head member 480, the irradiation member 500, the capturing member 700, and the lighting member 800 may be modularized and provided by the housing 460.

An opening may be formed at a lower portion of the housing 460. The head member 480, which will be described below, may be inserted into the opening of the housing 460. For example, a barrel of the head member 480 may be inserted into the opening of the housing 460. As illustrated in FIGS. 4 and 6, as the head member 480 is inserted into the opening of the housing 460, a portion of the barrel of the head member 480 may protrude from a lower end of the housing 460.

Referring to FIGS. 4 and 5, the movement member 470 is coupled to the housing 460. The movement member 470 moves the housing 460. The movement member 470 may move the housing 460 to move the head member 480. The movement member 470 may include a driving machine 472 and a shaft 474.

The driving machine 472 may be a motor. The driving machine 472 may be connected to the shaft 474. The driving machine 472 may vertically move the shaft 474. Further, the driving machine 472 may rotate the shaft 474. Although not illustrated, a plurality of driving machines 472 according to the embodiment may be provided. One of the plurality of driving machines may be provided as a rotary motor for rotating the shaft 474, and another one of the plurality of driving machines may be provided as a linear motor for vertically moving the shaft 474.

The shaft 474 is coupled to the housing 460. As the shaft 474 rotates by the driving machine 472, the housing 460 also rotates. Accordingly, the position of the head member 480, which will be described below, on a horizontal surface may change. Further, as the shaft 474 vertically moves by the driving machine 472, and the housing 460 also vertically moves. Accordingly, the height of the head member 480, which will be described below, on a horizontal surface may change.

According to the embodiment, the head member 480 may include a barrel and an objective lens. The head member 480 may irradiate the substrate “M” supported by the support unit 420 with light. The head member 480 may irradiate the substrate “M” with light received from the irradiation member 500, which will be described below. The light with which the substrate “M” is irradiated by the head member 480 may heat a partial region formed in the substrate “M”. For example, the light with which the substrate “M” is irradiated may heat the second pattern P2 among the first pattern P1 and the second pattern P2.

When viewed from the top, the center of the head member 480 may move while forming an arc. When viewed from the top, the center of the head member 480 may move to pass through a center of the substrate “M” supported by the support unit 420. The head member 480 may move between an irradiation position in which the substrate “M” is heated as the movement member 470 irradiates the substrate “M” with light and a standby position in which the head member 480 stands by without performing the heat treatment on the substrate “M”.

According to the embodiment, the irradiation position may be an upper portion of the second pattern P2 formed on the substrate “M” supported by the support unit 420. The standby position may be provided outside the treatment container 430. Further, in the standby position, a groove port that is not illustrated is provided, and in the groove port (not illustrated), maintenance work on components included in the laser unit 450 may be performed.

Referring back to FIGS. 6 and 7, the irradiation member 500 may provide light to the head member 480. For example, the light provided to the head member 480 by the irradiation member 500 may be a laser beam. The irradiation member 500 may include an oscillation unit 520, an expander 540, and a diffraction unit 560. According to the embodiment, the oscillation unit 520, the expander 540, and the diffraction unit 560 may be arranged in the first direction X.

The oscillation unit 520 emits light. For example, the oscillation unit 520 may emit a laser beam. The oscillation unit 520 may emit light in the first direction X. That is, a path of the light emitted from the oscillation unit 520 may be directed in the first direction X. Output of the light emitted from the oscillation unit 520 may change.

A tilting member 522 may be installed in the oscillation unit 520. The tilting member 522 may tilt a direction in which the light emitted from the oscillation unit 520 is emitted. For example, the tilting member 522 may be provided as a motor. The tilting member 522 may rotate the oscillation unit 520 about one axis. The tilting member 522 may rotate the oscillation unit 520 to tilt the direction in which the light emitted from the oscillation unit 520 is emitted.

The expander 540 is disposed between the oscillation unit 520 and the diffraction unit 560, which will be described below. The expander 540 receives the light emitted from the oscillation unit 520. The expander 540 may change a profile of the light received from the oscillation unit 520. According to the embodiment, the expander 540 may be provided as a variable beam expander telescope (BET). The profile may mean characteristics of light, such as the intensity of light, the diameter of light, the shape of the light, focal distribution of light, and the asymmetry of light. For example, the expander 540 may change a profile such as focus dispersion by adjusting a diameter and/or a divergence angle of the light emitted from the oscillation unit 520.

The expander 540 may transfer the light emitted from the oscillation unit 520 to the diffraction unit 560. For example, the expander 540 may transfer the light having the changed profile to the diffraction unit 560. Further, the expander 540 may transfer the light having the profile that is not changed to the diffraction unit 560. A detailed mechanism in which the expander 540 changes the profile of the light emitted from the oscillation unit 520 will be described below.

The light emitted from the oscillation unit 520 is transferred to the diffraction unit 560 via the expander 540. The diffraction unit 560 receives the light from the expander 540. For example, the diffraction unit 560 may receive the light having a profile that is not changed in the expander 540. Further, the diffraction unit 560 may receive the light having the changed profile in the expander 540.

The diffraction unit 560 may change the profile of the received light. The diffraction unit 560 may change the profile of the light, which is not changed in the expander 540. For example, the diffraction unit 560 may separate the light having a profile that is not changed in the expander 540 into a plurality of light bundles. Further, the diffraction unit 560 may change the profile of the light having the changed profile in the expander 540 again. For example, the diffraction unit 560 may separate the light having the changed profile into a plurality of light bundles in the expander 540. According to the embodiment, the diffraction unit 560 may be provided as a diffractive optical element (DOE). Further, the diffraction unit 560 may be provided as the DOE that transmits light.

The diffraction unit 560 may separate the received light into the plurality of light bundles to change the number of light bundles with which the substrate “M” supported by the support unit 420 is irradiated per unit area. That is, the diffraction unit 560 may separate the light bundles included in a reference light beam to change the intensity of the light with which the substrate “M” is irradiated per unit area. A mechanism in which the profile of the light transferred to the diffraction unit 560 is changed will be described in detail below.

The lower reflective plate 600 is positioned on the path of the light emitted from the oscillation unit 520. According to the embodiment, when viewed from the side, the lower reflective plate 600 may be positioned at a height corresponding to the oscillation unit 520, the expander 540, and the diffraction unit 560. Further, when viewed from the top, the lower reflective plate 600 may be provided at a position corresponding to the head member 480.

The lower reflective plate 600 may change the path of the light emitted from the oscillation unit 520. The lower reflective plate 600 may change an irradiation direction of light irradiated in a horizontal direction to a vertical downward direction. For example, the lower reflective plate 600 may change an irradiation direction of light irradiated in the first direction X that is the light path, to the third direction Z. The light having the irradiation direction changed to the third direction Z may be transferred to the head member 480.

According to the embodiment, the light emitted from the oscillation unit 520 may be transferred to the lower reflective plate 600 sequentially through the expander 540 and the diffraction unit 560. The light transmitted to the lower reflective plate 600 may be light having a profile that is not changed. Further, the light transmitted to the lower reflective plate 600 may be light having a profile that is changed.

Hereinafter, for convenience of understanding, when the light transferred to the substrate “M” through the lower reflective plate 600 and the head member 480 is the light having the changed profile, this light is defined as an adjustment light. For example, the adjustment light may be the light having a profile that is changed by the expander 540. Further, the adjustment light may be the light having a profile that is changed by the diffraction unit 560. Further, the adjustment light may be light having the profile that is changed by the expander 540 and is then changed by the diffraction unit 560 in turn.

The light transferred to the lower reflective plate 600 may be transferred to the head member 480 and irradiated to the substrate “M”. For example, the light emitted from the oscillation unit 520 may be irradiated onto the second pattern P2 formed on the substrate “M” sequentially through the expander 540, the diffraction unit 560, the lower reflective plate 600, and the head member 480.

Further, when viewed from the top, the lower reflective plate 600 may be positioned to overlap an upper reflective plate 960, which will be described below. The lower reflective plate 600 may be disposed below the upper reflective plate 960. The lower reflective plate 600 may be tilted by the same angle as the upper reflective plate 960.

The capturing member 700 photographs the light with which the substrate “M” is irradiated and acquires an image therefor. Further, the capturing member 700 may photograph the light with which the groove port (not illustrated) is irradiated and acquire an image therefor. The image obtained by the capturing member 700 may be an image and/or a picture. The capturing member 700 may transmit the acquired image to the controller 30. The controller 30 may analyze the image to monitor and analyze the profile of the light with which the substrate “M” and/or the groove port (not illustrated) is irradiated.

The capturing member 700 obtains an image for a target object by photographing the target object. The capturing member 700 obtains an image of the light with which the substrate “M” supported by the support unit 420 is irradiated. For example, the capturing member 700 may acquire an image including a point of the substrate “M” irradiated with light. Likewise, the light with which the substrate “M” is irradiated may be light having a profile that is not changed. Further, the light with which the substrate “M” is irradiated may be light having a profile that is changed. Further, the capturing member 700 may acquire an image of the substrate “M” supported by the support unit 420. Further, the capturing member 700 may acquire an image of light with which the groove port (not illustrated) is irradiated.

According to the embodiment, the capturing member 700 may be a camera. A direction in which the capturing member 700 performs photographing to acquire the image may be a direction toward the upper reflective plate 960.

The lighting member 800 may provide light so that the capturing member 700 may easily acquire the image. The light provided by the lighting member 800 may be provided toward a first reflective plate 920, which will be described below. Further, the light provided by the lighting member 800 may be directed toward the upper reflective plate 960 sequentially through the first reflective plate 920 and a second reflective plate 940, which will be described below.

The upper reflective member 900 may include the first reflective plate 920, the second reflective plate 940, and the upper reflective plate 960.

The first reflective plate 920 and the second reflective plate 940 change the irradiation direction of the light of the lighting member 800. The first reflective plate 920 and the second reflective plate 940 may be installed at heights corresponding to each other. The first reflective plate 920 may reflect the light irradiated by the lighting member 800 toward the second reflective plate 940. For example, the first reflective plate 920 may change the light irradiated by the lighting member 800 in the first direction X so that the light is directed to the second direction Y. The second reflective plate 940 may reflect the light reflected by the first reflective plate 920 toward the upper reflective plate 960 in turn. For example, the second reflective plate 940 may change the light reflected by the first reflective plate 920 in the second direction Y so that the light is directed to the first direction X toward the upper reflective plate 960.

The upper reflective plate 960 may change a capturing direction of the capturing member 700. For example, the upper reflective plate 960 may change the capturing direction of the capturing member 700 that is a horizontal direction to a vertically downward direction. For example, the upper reflective plate 960 may change the capturing direction of the capturing member 700 so that the capturing direction is directed toward the head member 480.

Further, the upper reflective plate 960 may change an irradiation direction of the light irradiated by the lighting member 800. For example, the upper reflective plate 960 may change the irradiation direction of the light transferred sequentially through the first reflective plate 920 and the second reflective plate 940 so that the irradiation direction may be changed from the horizontal direction to the vertically downward direction. For example, the upper reflective plate 960 may change the irradiation direction of the light irradiated by the lighting member 800 so that the irradiation direction is directed to the head member 480.

When viewed from the top, the upper reflective plate 960 and the lower reflective plate 600 may be positioned to overlap each other. The upper reflective plate 960 may be disposed above the lower reflective plate 600. The upper reflective plate 960 and the lower reflective plate 600 may be tilted by the same angle. The upper reflective plate 960 and the lower reflective plate 600 may be formed such that the irradiation direction of the light irradiated from the lighting member 500, the capturing direction of the capturing member 700, and the irradiation direction of the light provided by the lighting member 800 have the same axis. The capturing member 700, the lighting member 800, the first reflective plate 920, and the second reflective plate 940 may be modularized and provided in the installation space of the housing 460.

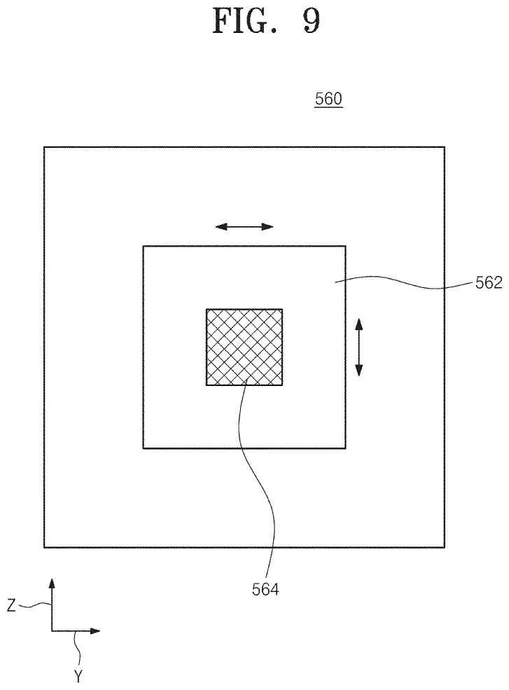

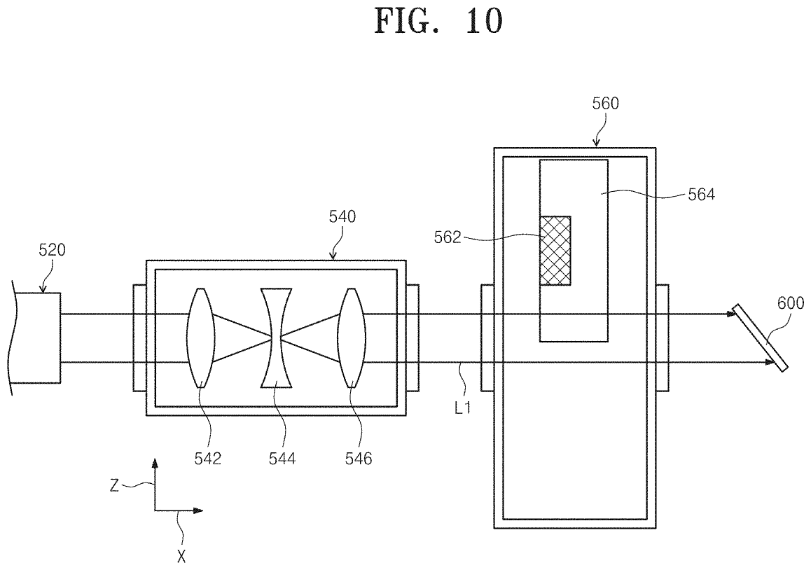

FIG. 8 is a schematic view illustrating a state in which an expander and a diffraction unit of FIG. 6 according to the embodiment are viewed from the lateral side. FIG. 9 is a schematic view illustrating a state in which the diffraction unit of FIG. 8 according to the embodiment is viewed from the front side.

Hereinafter, the expander 540 and the diffraction unit 560 according to the embodiment of the present disclosure will be described in detail with reference to FIGS. 8 and 9.

The oscillation unit 520, the expander 540, and the diffraction unit 560 may be arranged in the first direction X. Further, the oscillation unit 520, the expander 540, and the diffraction unit 560 may be sequentially arranged. The oscillation unit 520, the expander 540, and the diffraction unit 560 may be combined with each other to form a light path. The light emitted from the oscillation unit 520 may be transferred to the expander 540, and the light transferred to the expander 540 may be transferred to the diffraction unit 560. The light transferred to the diffraction unit 560 may be irradiated onto the substrate “M” supported by the support unit 420 through the lower reflective plate 600 and the head member 480 illustrated in FIG. 6.

The expander 540 may change a profile of the light received from the oscillation unit 520. According to the embodiment, the expander 540 may change the diameter, the divergence angle, or the like of the light transferred from the oscillation unit 520. The expander 540 may include a plurality of lenses. The expander 540 may include a first lens 542, a second lens 544, and a third lens 546.

The first lens 542, the second lens 544, and the third lens 546 are positioned on the light path. The first lens 542, the second lens 544, and the third lens 546 may be sequentially arranged in a direction from the oscillation unit 520 toward the diffraction unit 560. The light emitted from the oscillation unit 520 may be transferred to the diffraction unit 560 sequentially through the first lens 542, the second lens 544, and the third lens 546. The profile of the light emitted from the oscillation unit 520 may be changed while the light passes through the first lens 542, the second lens 544, and the third lens 546.

According to the embodiment, the first lens 542 and the second lens 544 may be provided to be movable. The first lens 542 and the second lens 544 may be provided to be movable in a horizontal direction. For example, the first lens 542 and the second lens 544 may move forward or rearward in the first direction X. A position of the third lens 546 may be fixedly provided. According to the embodiment, the first lens 542 and the third lens 546 may be provided as convex lenses. Further, the second lens 544 may be provided as a concave lens.

However, the present disclosure is not limited thereto, and the first lens 542, the second lens 544, and the third lens 546 may be provided as any one of the concave lens and/or the convex lens. Further, in the above example, it has been described that the expander 540 includes the first lens 542, the second lens 544, and the third lens 546, but the present disclosure is not limited thereto. For example, the expander 540 may include an integer number of lenses, which is greater than or equal to four.

The diffraction unit 560 receives the light from the expander 540. The light transferred to the diffraction unit 560 may be light having a profile changed by the expander 540. Further, the light transferred to the diffraction unit 560 may be light having a profile not changed by the expander 540. The diffraction unit 560 may separate the light transferred from the expander 540 into a plurality of light bundles.

The diffraction unit 560 may change a profile of the light received from the expander 540. According to the embodiment, the diffraction unit 560 may change the number of light bundles per unit area of the light transferred from the expander 540. Accordingly, the diffraction unit 560 may change the intensity of light per unit area of the light received from the expander 540.

The diffraction unit 560 may include a body 562 and a diffraction plate 564. The body 562 may be made of a material that does not change a path of input light. According to the embodiment, the body 562 may be a mirror. The diffraction plate 564 may be inserted into the body 562. According to the embodiment, as illustrated in FIG. 9, when viewed from the front side, the diffraction plate 564 may be inserted into a central portion of the body 562. The body 562 may be provided to be movable. The body 562 may move in the horizontal direction and the vertical direction. For example, the body 562 may move in the first direction X, the second direction Y, and the third direction Z.

The diffraction plate 564 may be inserted into the body 562. For example, when viewed from the top, the diffraction plate 564 may be inserted into a central portion of the body 562. The diffraction plate 564 may be a diffraction element that separates the light transferred from the expander 540 into the light bundles. Further, a plurality of protrusions for diffracting the light may be formed on the surface of the diffraction plate 564. When viewed from the front side, the diffraction plate 564 may have a substantially circular shape. According to the embodiment, the diffraction plate 564 may have a diameter corresponding to a diameter of light having a reference profile, which will be described below. However, the present disclosure is not limited thereto, and the diffraction plate 564 may have various shapes.

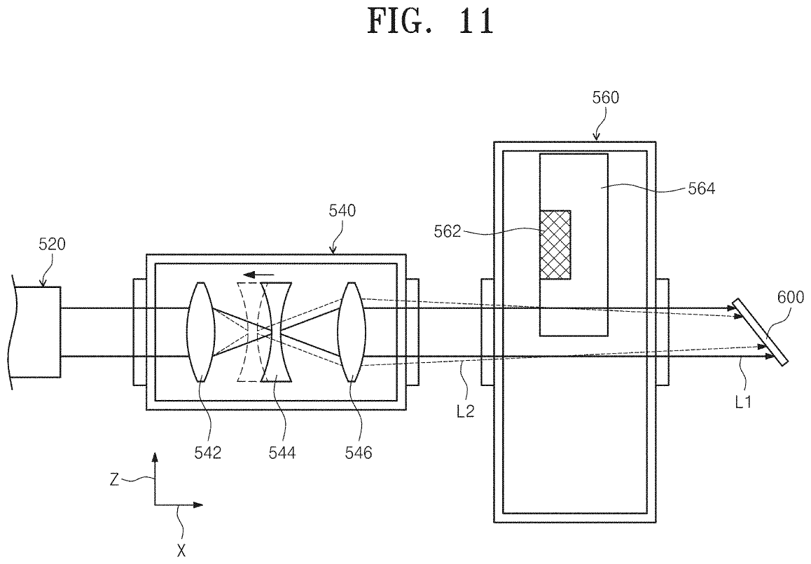

Hereinafter, a mechanism in which the laser unit 450 irradiates the substrate “M” with light according to the embodiment of the present disclosure will be described in detail with reference to FIGS. 10 to 15. The mechanism in which the laser unit 450 irradiates the substrate “M” with light may be performed by the controller 30. The controller 30 may control components included in the substrate treatment apparatus 1 according to the embodiment of the present disclosure. For example, the controller 30 may control components included in the liquid treatment chamber 400.

FIG. 10 is a schematic view illustrating a state of light moving along a light path and having a reference profile in the laser unit of FIG. 6 according to the embodiment. Referring to FIG. 10, when the components 542, 544, and 546 included in the expander 540 and the components 562 and 564 included in the diffraction unit 560 are positioned at reference positions, the profile of the light emitted from the oscillation unit 520 may not be changed in the expander 540 and the diffraction unit 560.

For example, the reference position of the diffraction unit 560 may mean a position at which the body 562 moves in the vertical direction (for example, the third direction Z) and thus the diffraction plate 564 is not provided on the light path. The reference position of the diffraction unit 560 may mean a position at which the body 562 moves in the vertical direction and thus the diffraction plate 564 is disposed outside the light transferred from the expander 540.

When the components 542, 544, and 546 included in the expander 540 and the components 562 and 564 included in the diffraction unit 560 are positioned at the reference positions, the light irradiated from the oscillation unit 520 has a reference profile such as a reference output, a reference shape, and a reference focus distribution, and may be irradiated onto the substrate “M” supported by the support unit 420 sequentially through the lower reflective plate 600 and the head member 480. Data for the reference profile may be a value stored in the controller 30 in advance.

According to the embodiment, a light L1 having the reference profile may have a flat-top shape. Further, when viewed from the top, the light L1 having the reference profile may have a substantially circular shape. Further, the light L1 having the reference profile may be provided such that the intensity per unit area of the light with which the substrate “M” is irradiated is the same.

As illustrated in FIG. 10, all the first lens 542, the second lens 544, and the body 562 are arranged at the reference positions. The light emitted from the oscillation unit 520 is transferred to the first lens 542. The light transferred to the first lens 542 is transferred to the second lens 544 and the third lens 546. The light transferred to the third lens 546 is transferred to the diffraction plate 564. When the first lens 542 and the second lens 544 are positioned at the reference positions, the light passing through the third lens 546 may be transferred to an outer region of the diffraction plate 564. The light transferred to the body 562 may be transferred to the lower reflective plate 600, and the light transferred to the lower reflective plate 600 may be irradiated onto the substrate “M” supported by the support unit 420 through the head member 480 illustrated in FIG. 6. All the light transferred to the first lens 542, the second lens 544, the third lens 546, the diffraction unit 560, and the lower reflective plate 600 may be the light L1 having the reference profile.

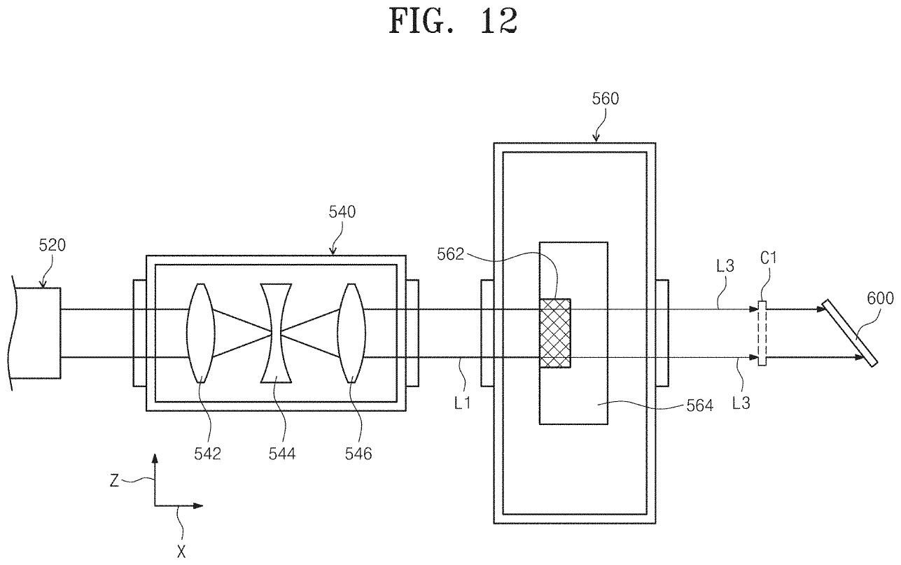

FIG. 11 is a schematic view illustrating a state in which the expander of FIG. 6 according to the embodiment changes a profile of light having the reference profile. Hereinafter, a mechanism in which the expander changes the profile of the light having the reference profile will be described with reference to FIG. 11. In the following embodiment, an example of a case in which the diffraction unit 560 is positioned at the reference position and the second lens 544 among the first lens 542 and the second lens 544 moves will be described. However, the present disclosure is not limited thereto, and both the first lens 542 and the second lens 544 may move to change the profile of the light emitted from the oscillation unit 520. Further, the first lens 542 among the first lens 542 and the second lens 544 may move to change the profile of the light emitted from the oscillation unit 520.

The second lens 544 may move in the horizontal direction (for example, the first direction X) from the reference position. For example, the second lens 544 may move in a direction toward the first lens 542 from the reference position. In this case, the profile of the light transferred to the second lens 544 is changed by the second lens 544. For example, the profile of the light transferred to the second lens 544 may be changed to increase the divergence angle thereof. The light of which the profile is changed by the second lens 544 may be defined as an adjustment light L2. The adjustment light L2 may be irradiated onto the substrate “M” sequentially through the third lens 546, the diffraction unit 560, the lower reflective plate 600, and the head member 480 illustrated in FIG. 6. According to the embodiment, the adjustment light L2 with which the substrate “M” is irradiated may have a relatively reduced diameter as compared to the light L1 having the reference profile.

The expander 540 according to the embodiment of the present disclosure may change the profile of the light emitted from the oscillation unit 520. For example, the expander 540 may change the profile by increasing or decreasing the diameter of the light. Further, the expander 540 may change the profile by adjusting a size of a spot of the light with which the substrate “M” is irradiated by changing the divergence angle of the light. Accordingly, the focal distribution of a central portion or an edge portion of the light with which the substrate “M” is irradiated may be changed.

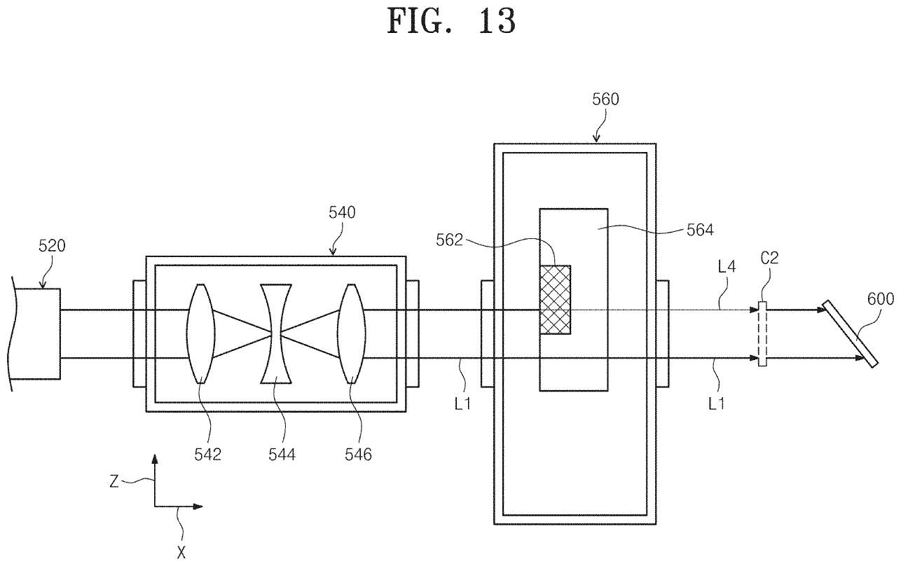

FIGS. 12 and 13 are schematic views illustrating a state in which the diffraction unit of FIG. 6 according to the embodiment changes the profile of light having the reference profile.

Hereinafter, a mechanism in which the diffraction unit changes the profile of light having a reference profile will be described. In the following description, an example of a case in which the components 542 and 544 included in the expander 540 and the diffraction unit 560 moves will be described. However, the present disclosure is not limited thereto, and all the components 542 and 544 included in the expander 540 and the diffraction unit 560 may move to change the profile of the light emitted from the oscillation unit 520.

As illustrated in FIG. 12, the diffraction unit 560 may move in the vertical direction and the horizontal direction. The diffraction unit 560 may move in the first direction X, the second direction Y, and the third direction Z. For example, the body 562 may move in the third direction Z so that diffraction plate 564 may be positioned on the light path. The light emitted from the oscillation unit 520 may be transferred to the diffraction plate 564 through the first lens 542, the second lens 544, and the third lens 546. The light transferred to the diffraction plate 564 may be the light L1 having the reference profile. All the light L1 having the reference profile, passing through the first lens 542, the second lens 544, and the third lens 546 may be transferred to the diffraction plate 564.

The light L1 having the reference profile, transferred to the diffraction plate 564, may be separated into the light bundles. The light L1 having the reference profile, transferred to the diffraction plate 564, may be separated into the light bundles, and the profile thereof may be changed to a profile of an adjustment light L3 having a changed profile. For example, the light transferred to the diffraction plate 564 may be separated into the light bundles while colliding a protrusion formed in the diffraction plate 564. The number of light bundles per unit area of the transferred light may change by the diffraction plate 564. That is, the intensity of light per unit area of the transferred light may be changed by the diffraction plate 564.

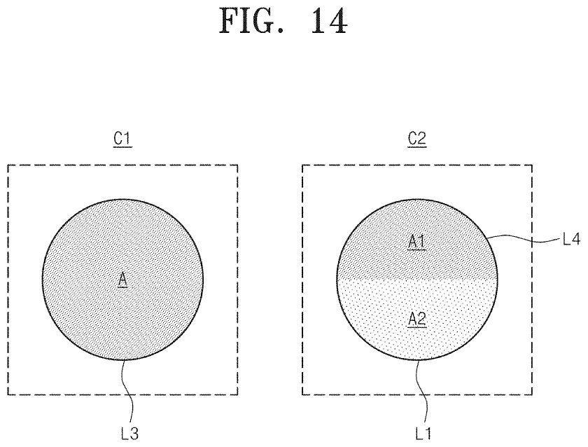

FIG. 14 is an enlarged view of portion C1 of FIG. 12 when viewed from the front side. As illustrated in FIG. 14, in the adjustment light L3 having the profile changed through the diffraction plate 564, the number of light bundles per unit area may increase in the entire region “A”. Further, in the adjustment light L3 having the profile changed through the diffraction plate 564, the intensity of light per unit area may increase in the entire region “A”. The adjustment light L3 having the profile changed by the diffraction plate 564 may be transferred to the lower reflective plate 600, and the substrate “M” supported by the support unit 420 may be irradiated with the adjustment light L3 having the changed profile and transferred to the lower reflective plate 600 through the head member 480. Accordingly, the intensity per unit area of the adjustment light L3 with which the substrate “M” is irradiated may increase in the entire region A.

FIG. 14 is an enlarged view of portion C2 of FIG. 13 when viewed from the front side. Referring to FIGS. 13 and 14, the oscillation unit 520 and the expander 540 may be combined with each other to form the light path that is a path through which the light moves. The light path may include the first region A1 and the second region A2. The first region A1 and the second region A2 may be regions different from each other. Hereinafter, for convenience of understanding, the first region A1 may be defined as an upper region of the light path, and the second region A2 may be defined as a lower region of the light path.

The light transferred to the diffraction plate 564 may be the light L1 having the reference profile. A portion of the light L1 having the reference profile, passing through the first lens 542, the second lens 544, and the third lens 546, may be transferred to the diffraction plate 564, and the other portion thereof may be transferred to the body 562. Further, the other portion may be transferred to the outer region of the diffraction plate 564.

For example, the body 562 may move in the third direction Z. The body 562 may move in the third direction Z and allow a partial region (for example, the first region A1) of the light path and the diffraction plate 564 to be matched with each other when viewed from the front side. For example, as illustrated in FIG. 13, the body 562 may move in the third direction Z so that only the first region A1 among the path of the light formed by combining the oscillation unit 520 and the expander 540 with each other is transferred to the diffraction plate 564.

The profile of the light L1 having the reference profile, provided to the first region A1 among the light path, may be changed while passing through the diffraction plate 564. An adjustment light L4 having a changed profile may be irradiated onto the substrate “M” supported by the support unit 420 through the lower reflective plate 600 and the head member 480 illustrated in FIG. 6. Further, the light L1 having the reference profile provided to the second region A2 among the light path passes the body 562, and thus the light L1 may be transferred to the lower reflective plate 600 without changing the profile thereof. The light L1 having the reference profile, provided to the lower reflective plate 600, may be irradiated onto the substrate “M” supported by the support unit 420 through the head member 480 illustrated in FIG. 6.

That is, as illustrated in FIG. 14, the intensity of light per unit area of the light L4 provided to the first region A1 may be relatively greater than the intensity of the light L1 provided to the second region A2 because the profile of the light L4 is changed by the diffraction plate 564. Accordingly, the intensity per unit area of the light with which the substrate “M” is irradiated may have asymmetry.

Although it has been described in the above embodiment that the light path is divided into the first region and the second region, the present disclosure is not limited thereto. For example, the light path may be divided into a plurality of regions that do not overlap each other.

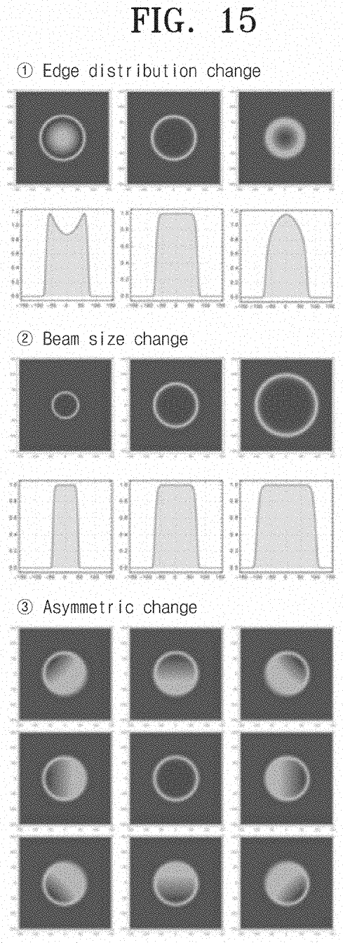

FIG. 15 is a view illustrating comparison in the embodiment in which the profile of the light is changed in the laser unit of FIG. 6 according to the embodiment. The adjustment light having a profile changed by the expander 540 and/or the diffraction unit 560, according to the embodiment of the present disclosure may be irradiated onto the substrate “M” supported by the support unit 420.

For example, as illustrated in FIG. 15, the diameter of the light or the divergence angle of the light is changed by the expander 540, and thus the size of the spot of the light with which the substrate “M” is irradiated may be changed or the diameter of the light irradiated onto the substrate “M” may be changed. Accordingly, the focal distribution of the central region and the edge region of the light with which the substrate “M” is irradiated may be adjusted.

Further, the intensity per unit area of the light with which the substrate “M” is irradiated by the diffraction unit 560 may be changed. For example, as illustrated in FIG. 15, the intensity per unit area of the light irradiated onto an upper region among the entire region of the light with which the substrate “M” is irradiated may relatively increase. Further, the intensity per unit area of the light irradiated onto a left region among the entire region of the light with which the substrate “M” is irradiated may relatively increase. Accordingly, a specific region that requires concentration of light may be selectively irradiated with the light having the adjusted intensity per unit area.

According to the embodiment of the present disclosure, the laser unit 450 may irradiate the second pattern P2 among the first pattern P1 and the second pattern P2 formed on the substrate “M” with light. For example, as the laser unit 450 irradiates the second pattern P2 with the light, the critical dimension of the first pattern P1 is changed from the first width (for example, 69 nm) to a target critical dimension (for example, 70 nm), and the critical dimension of the second pattern P2 is changed from a second width (for example, 68.5 nm) to the target critical dimension (for example, 70 nm).

That is, the laser unit 450 according to the embodiment of the present disclosure may etch the partial region on the substrate “M”, and thus the deviation in the critical dimension of the pattern formed on the substrate “M” should be minimized. Accordingly, the expander 540 and the diffraction unit 560 according to the embodiment of the present disclosure may efficiently change the profile of the light emitted from the oscillation unit 520 to efficiently etch a specific pattern or a partial region. In particular, since the plurality of second patterns P2 according to the embodiment of the present disclosure may be arranged in series and/or parallel combinations, the profile of the light with which the second patterns P2 are irradiated may be flexibly changed according to the shapes of the various second patterns P2.

Further, even when a working distance between the head member 480 and the substrate “M” supported by the support unit 420 is changed, the profile of the light with which the substrate “M” is irradiated may be appropriately changed. Accordingly, a specific pattern may be uniformly irradiated with the light having the profile that satisfies a process requirement condition.

In the embodiments of the present disclosure, for convenience of understanding, an example of a case in which the profile of the light is changed only by the expander 540 or the profile of the light is changed only by the diffraction unit 560 has been described, but the present disclosure is not limited thereto. For example, the profile of the light emitted from the oscillation unit 520 may be changed by the expander 540, the light having the profile changed by the expander 540 is received from the diffraction unit 560, and the profile of the light having the profile changed may be changed in turn by the diffraction unit 560.

An example in which a treatment process performed in the liquid treatment chamber performs the FCC during the process of manufacturing the mask for the exposure process, but the present disclosure is not limited thereto. For example, the to-be-treated object treated in the liquid treatment chamber 400 may be provided as a wafer or glass. Further, the process performed in the liquid treatment chamber 400 may be any one process except for the FCC among the process of manufacturing the mask. Further, the process performed by the liquid treatment chamber 400 may include various processes using a liquid, such as a cleaning process or a photo process in addition to the exposure process.

In the embodiment of the present disclosure, an example in which an etching rate of the second pattern P2 is improved in the substrate “M” having the first pattern P1 that is a monitoring pattern for monitoring an exposure pattern and the second pattern P2 that is a pattern for setting a condition for treating the substrate has been described. However, unlike this, functions of the first pattern P1 and the second pattern P2 may be different from the above embodiments of the present disclosure. Further, according to the embodiment of the present disclosure, only one pattern among the first pattern P1 and the second pattern P2 may be provided, and an etching rate of one pattern provided among the first pattern P1 and the second pattern P2 may be improved. Further, according to the embodiment of the present disclosure, the same can be applied when the etching rate of the specific region on the substrate such as a wafer or glass in addition to a photo mask is improved.

Further, the treating module 20 that has been described with reference to FIG. 2 may further include a drying chamber (not illustrated). The drying chamber (not illustrated) may be disposed on a lateral side of the transport frame 300 illustrated in FIG. 2. The drying chamber (not illustrated) may perform a drying process for drying the substrate “M” on which liquid treatment has been completed in the liquid treatment chamber.

According to the embodiment of the present disclosure, precise etching may be performed on a substrate.

Further, according to the embodiment of the present disclosure, selective etching may be performed on a specific region of the substrate.

Further, according to the embodiment of the present disclosure, uniform etching may be performed on the specific region of the substrate.

Further, according to the embodiment of the present disclosure, a profile of a laser light with which the substrate is irradiated may be flexibly changed.

Further, according to the embodiment of the present disclosure, selective etching on a specific region of the substrate may be performed by changing an intensity of light per unit area of a partial region among the entire region of the substrate with which the light is irradiated.

The effects of the present disclosure are not limited to the above-mentioned effects, and the unmentioned effects can be clearly understood by those skilled in the art to which the present disclosure pertains from the specification and the accompanying drawings.

The above detailed description exemplifies the present disclosure. Furthermore, the above-mentioned contents describe the exemplary embodiment of the present disclosure, and the present disclosure may be used in various other combinations, changes, and environments. That is, the present disclosure can be modified and corrected without departing from the scope of the present disclosure that is disclosed in the specification, the equivalent scope to the written disclosures, and/or the technical or knowledge range of those skilled in the art. The written embodiment describes the best state for implementing the technical spirit of the present disclosure, and various changes required in the detailed application fields and purposes of the present disclosure can be made. Accordingly, the detailed description of the present disclosure is not intended to restrict the present disclosure in the disclosed embodiment state. Furthermore, it should be construed that the attached claims include other embodiments.

What is claimed is:

1. A substrate treatment apparatus comprising:
a support unit configured to support a substrate;
a liquid supply unit configured to supply a liquid to the substrate supported by the support unit; and
a laser unit configured to heat the substrate supported by the support unit,
wherein the laser unit includes:
an oscillation unit configured to emit a light; and
a diffraction unit configured to separate the light into a plurality of light bundles and irradiate the substrate supported by the support unit with an adjustment light having a profile changed from a profile of the light.

2. The substrate treatment apparatus of claim 1, wherein the profile includes an intensity of light per unit area.

3. The substrate treatment apparatus of claim 2, wherein the diffraction unit is provided to movable on a path of the light emitted from the oscillation unit.

4. The substrate treatment apparatus of claim 3, wherein the light path includes a first region and a second region different from the first region,
the substrate treatment apparatus further includes a controller, and
the controller moves the diffraction unit in a direction toward the first region, separates the light input to the first region among the light emitted from the oscillation unit into a plurality of light bundles, and changes the profile of the light so that an intensity per unit area of the light in the first region is greater than an intensity per unit area of the light in the second region, the light passing through the diffraction unit.

5. The substrate treatment apparatus of claim 4, wherein the laser unit further includes an expander configured to change a diameter of the light, and
the expander is provided between the oscillation unit and the diffraction unit.

6. The substrate treatment apparatus of claim 5, wherein the profile further includes the diameter of the light or a distribution of the light,
the expander includes a plurality of lenses, and
the controller changes the profile of the light by changing a distance between the plurality of lenses on the light path.

7. The substrate treatment apparatus of claim 1, wherein the laser unit further includes a capturing member configured to capture the adjustment light on the support unit, and
an irradiation direction of the adjustment light with which the substrate supported by the support unit is irradiated and a capturing direction of the capturing member have the same axis when viewed from the top.

8. A substrate treatment apparatus for treating a mask having a plurality of cells, the substrate treatment apparatus comprising:
a support unit configured to support the mask in which a first pattern is formed inside the plurality of cells and a second pattern different from the first pattern is formed outside regions in which the cells are formed;
a liquid supply unit configured to supply a liquid to the mask supported by the support unit; and
a laser unit configured to heat the mask supported by the support unit,
wherein the laser unit includes:
an oscillation unit configured to emit light;
an expander configured to change a diameter of the light; and
a diffraction unit configured to separate the light into a plurality of light bundles and irradiate a substrate supported by the support unit with an adjustment light having a profile changed from a profile of the light.

9. The substrate treatment apparatus of claim 8, wherein the profile includes an intensity of the light per unit area, a diameter of the light, or a distribution of the light.

10. The substrate treatment apparatus of claim 9, wherein the diffraction unit is provided to be movable on a path of the light emitted from the oscillation unit.

11. The substrate treatment apparatus of claim 10, wherein the expander is provided between the oscillation unit and the diffraction unit.

12. The substrate treatment apparatus of claim 10, wherein the light path includes a first region and a second region different from the first region,
the substrate treatment apparatus further includes a controller, and
the controller moves the diffraction unit in a direction toward the first region, separates the light input to the first region among the light emitted from the oscillation unit into a plurality of light bundle, and changes the profile of the light so that an intensity per unit area of the light in the first region is greater than an intensity per unit area of the light in the second region, the light passing through the diffraction unit.

13. The substrate treatment apparatus of claim 12, wherein the expander includes a plurality of lenses, and
the controller changes the profile of the light by changing a distance between the plurality of lenses on the light path.

14. The substrate treatment apparatus of claim 8, wherein the laser unit further includes a capturing member configured to capture the adjustment light with which the substrate supported by the support unit is irradiated, and
an irradiation direction of the adjustment light with which the substrate supported by the support unit is irradiated and a capturing direction of the capturing member have the same axis when viewed from the top.

15. The substrate treatment apparatus of claim 8, wherein the laser unit irradiates the second pattern among the first pattern and the second pattern with the adjustment light.

16-20. (canceled)
